(19) United States
(12) Patent Application Publication
(10) Pub. No.: US 2009/0266599 A1
(43) Pub. Date: Oct. 29, 2009

(54) Circuit board with high thermal conductivity and method for manufacturing the same

(75) Inventors: Ming-Chi Kan, Rende Township (TW); Shao-Chung Hu, Sindian City (TW)

Correspondence Address: BACON & THOMAS, PLLC, 625 SLATERS LANE, FOURTH FLOOR, ALEXANDRIA, VA, 22314-1176, US

(73) Assignee: Kinik Company, Taipei (TW)

(21) Appl. No.: 12/222,199

(22) Filed: Aug. 5, 2008

(30) Foreign Application Priority Data
Apr. 24, 2008 (TW) 097114999

(51) Int. Cl. H05K 1/11; B05D 5/12; C23C 14/34; C25D 3/00

(52) U.S. Cl. 174/263; 427/97.4; 216/17; 204/192.17; 205/261

(57) ABSTRACT

A circuit board having high thermal conductivity comprises a substrate, a plurality of thermal conductive insulating layers, a patterned electrical conductive layer, a plurality of through-holes and a soldering layer. The substrate has an upper surface and a lower surface; the thermal conductive insulating layers are respectively formed on the upper surface and the lower surface of the substrate. The patterned electrical conductive layer is disposed on the surfaces of the thermal conductive insulating layers. The plurality of through-holes are extended through the substrate and electrically connected to the patterned electrical conductive layer, and the soldering layer is partially formed on the patterned electric conductive layer. The present invention also discloses a method for manufacturing the circuit board as above-mentioned.

### BACKGROUND OF THE INVENTION

1. Field of the Invention

The present invention relates to a circuit board and a method for manufacturing the same and, more particularly, to a circuit board with high thermal conductivity and a method for manufacturing the same.

2. Description of Related Art

As the electronic industry develops rapidly, the demands for electronic products increase greatly. Additionally, the development in the electronics industry trends towards manufacturing electronic products with multifunction and high performance. Especially, as the growth and the utility in portable electronic products increase, the size of electronic products is reduced to meet the requirements of compactness and lightness. Hence, the size of circuit boards used in electronic products is also reduced. However, the reduced size of circuit boards makes heat dissipation more difficult.

For example, conventional light emitting diode devices (LEDs) can be applied in various electronic devices, such as backlight sources of display devices, mini-projectors, and lighting devices, due to its high brightness. However, 80% input power of LEDs is converted into heat. If the heat cannot be dissipated appropriately, the junction temperature of the LEDs will rise which influences the brightness and the lifetime thereof.

A multilayer substrate disclosed in JP 2004-193283 is used for supporting electronic components, wherein the multilayer substrate is a laminate, which consists of a ceramic substrate, an insulating layer, and a diamond layer. Electrodes are formed on the bottom or top face of the supporting substrate, and electrically bonded to each other through via-holes filled up with metal. The aforementioned multilayer substrate comprises the ceramic substrate and the ceramic insulating layer. However, use of ceramic material as the multilayer substrate still has a disadvantage in poor heat dissipation. Hence, the heat generated by continuous operation of the electronic components cannot be dissipated efficiently, which will influence the stability and the lifetime of the electronic components.

Therefore, it is desirable to provide a circuit board for supporting electronic components to improve the thermal conductivity and the heat dissipation of the electronic components.

### SUMMARY OF THE INVENTION

The object of the present invention is to provide a circuit board and a method for manufacturing the same to improve the thermal conductivity thereof, so that the heat generated by semiconductor devices can be dissipated rapidly.

To achieve the aforementioned object or other objects, the present invention provides a circuit board, comprising a substrate, a plurality of thermal conductive insulating layers, a patterned electrical conductive layer, a plurality of through-holes, and a solder layer. Herein, the substrate has an upper surface, and a lower surface; the thermal conductive insulating layers are respectively formed on the upper surface and the lower surface of the substrate; the patterned electrical conductive layer is disposed on the surfaces of the thermal conductive insulating layers; the through-holes are extended through the substrate, and electrically connected to the patterned electrical conductive layer; and the solder layer is partially formed on the patterned electrical conductive layer. Beside, the present invention also provides a method for manufacturing the aforementioned circuit board.

According to the circuit board of a preferable embodiment in the present invention, the through-holes are filled with a conductive material, which comprises Cu, Ag, or a combination thereof.

The circuit board of a preferable embodiment in the present invention may further comprise a plurality of ceramic layers formed on the upper surface and the lower surface of the substrate, and located between the substrate and the thermal conductive insulating layers, wherein the material of the ceramic layers is oxide, nitride, or boride.

According to the circuit board of a preferable embodiment in the present invention, the substrate comprises a metal substrate, a semiconductor substrate, or a substrate made from other applicable materials. Herein, the material of the metal substrate is Al, Cu., or a combination thereof, and the material of the semiconductor substrate is Si, Ge, GeAs, or a combination thereof.

According to the circuit board of a preferable embodiment in the present invention, the material of the thermal conductive insulating layers comprises diamond-like carbon. Additionally, the thermal conductive insulating layers have a dopant, which is F, Si, N, B, or a combination thereof. The thermal conductive insulating layers may have a thickness of 0.1-30 μm. Preferably, the thermal conductive insulating layers have a thickness of 2-5 μm.

The circuit board of a preferable embodiment in the present invention may further comprise an insulating layer formed on the sides of the through-holes, wherein the material of the insulating layer is insulating gel, or a ceramic material.

According to the circuit board of a preferable embodiment in the present invention, the material of the patterned electrical conductive layer is Cr, Cu, Ni, Au, Ag, or a combination thereof.

The circuit board of a preferable embodiment in the present invention may further comprise a metal layer disposed on the patterned electrical conductive layer to enhance the adhesive strength with the electronic component. Herein, the metal layer is Ni, Au, Ag, Sn or Sn alloy, and a combination thereof.

According to the circuit board of a preferable embodiment in the present invention, the circuit board is used to support an electronic component, which is disposed on the patterned electrical conductive layer of the circuit board through the solder layer, and the electronic component is a chip, or a semiconductor device.

To achieve the aforementioned object or other object, the present invention provides a method for manufacturing a circuit board (with high thermal conductivity), comprising the following steps: providing a substrate having an upper surface, and a lower surface; forming a plurality of thermal conductive insulating layers, which are respectively formed on the upper surface and the lower surface of the substrate; forming a plurality of through-holes, which are extended through the substrate, and the thermal conductive insulating layers; forming an electrode layer on the surfaces of the thermal conductive insulating layers; removing parts of the electrode layer to form a patterned electrical conductive layer; and forming a solder layer, which is partially formed on the patterned electrical conductive layer.

According to the method for manufacturing a circuit board with high thermal conductivity of a preferable embodiment in the present invention, the through-holes are formed by wet etching, or machine drilling.

According to the method for manufacturing a circuit board of a preferable embodiment in the present invention, the material of the thermal conductive insulating layers is diamond-like carbon.

The method for manufacturing a circuit board of a preferable embodiment in the present invention may further comprise: adding a dopant into the thermal conductive insulating layers. Herein, the dopant is F, Si, N, B, or a combination thereof.

The method for manufacturing a circuit board of a preferable embodiment in the present invention may further comprise: filling the through-holes with a conductive material, wherein the conductive material is Cu, Ag, or a combination thereof.

The method for manufacturing a circuit board of a preferable embodiment in the present invention may further comprise: forming an insulating layer on the sides of the through-holes, wherein the material of the insulating layer is insulating gel, or a ceramic material.

According to the method for manufacturing a circuit board of a preferable embodiment in the present invention, the electrode layer is formed by sputtering, electroplating, or electroless plating.

According to the method for manufacturing a circuit board of a preferable embodiment in the present invention, the electrode layer is removed by etching.

According to the method for manufacturing a circuit board of a preferable embodiment in the present invention, the electrode layer has a thickness of 0.1-100 μm, or 20-40 μm.

The method for manufacturing a circuit board of a preferable embodiment in the present invention may further comprise: forming a metal layer on the patterned electrical conductive layer after forming the patterned electrical conductive layer. Herein, the metal layer comprises Ni, Au, Ag, Sn or Sn alloy, and a combination thereof.

The method for manufacturing a circuit board of a preferable embodiment in the present invention may further comprise: forming a plurality of ceramic layers on the upper surface and the lower surface of the substrate.

According to the method for manufacturing a circuit board of a preferable embodiment in the present invention, the ceramic layers are located between the substrate and the thermal conductive insulating layers.

According to the method for manufacturing a circuit board of a preferable embodiment in the present invention, the ceramic layers are formed by anodizing, or thermal treatment.

According to the method for manufacturing a circuit board of a preferable embodiment in the present invention, the material of the ceramic layers is oxide, nitride, or boride.

In conclusion, in the circuit board and the method for manufacturing the same provided by the present invention, thermal conductive insulating layers and ceramic layers are formed on a substrate, and through-holes extended through the substrate are electrically connected to a patterned electrical conductive layer, which is disposed over an upper surface and a lower surface of the substrate. Hence, the heat generated by electronic components can be effectively dissipated by the circuit board of the present invention. Therefore, the efficiency and the lifetime of electronic components can be improved by use of the circuit board of the present invention.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a circuit board according to an embodiment of the present invention;

FIGS. 2A to 2E are flow charts for illustrating a process for manufacturing a circuit board according to an embodiment of the present invention; and

FIG. 3 is a cross-sectional view of a circuit board according to another embodiment of the present invention.

### DETAILED DESCRIPTION OF THE PREFERRED EMBODIMENT

### Embodiment 1

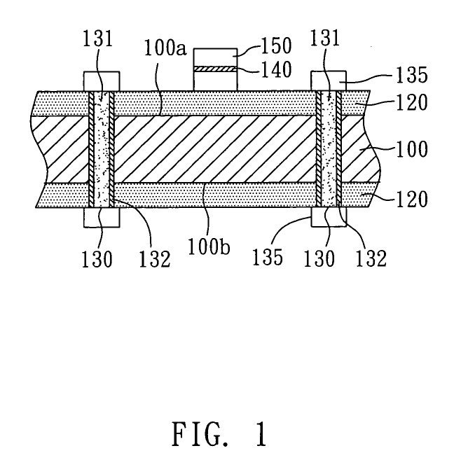

With reference to FIG. 1, there is shown a cross-sectional view of a circuit board according to an embodiment of the present invention. The circuit board of the present invention comprises: a substrate 100, a thermal conductive insulating layers 120, and a patterned electrical conductive layer 135. Herein, the thermal conductive insulating layers 120 are respectively formed on an upper surface 100a and a lower surface 100b of the substrate 100, and the patterned electrical conductive layer 135 is disposed on the surfaces of the thermal conductive insulating layers 120. The patterned electrical conductive layer 135 can be applied to electrically connect to other electronic components. For example, the patterned electrical conductive layer 135 is electrically connected to electronic components through wires. The material of the patterned electrical conductive layer 135 comprises materials with electrical conductivity, such as Cr, Cu, or Ag. Additionally, in the present embodiment, the substrate 100 is a substrate with thermal conductivity, which comprises a metal substrate, a semiconductor substrate, or a substrate made from other applicable material. It should be understood that any kinds of metal or semiconductor with the effect on heat dissipation can be used as the material of the substrate. Hence, in the present embodiment, the metal material comprises a metal or an alloy consisting of two or more metals, such as Al, Cu, an alloy thereof, or a compound thereof. The semiconductor material is, for example but not limited to, Si, Ge, GeAs, or a combination thereof.

In the present embodiment, the thermal conductive insulating layers 120 are formed on the upper surface 100a and the lower surface 100b of the substrate 100. Here, the thermal conductive insulating layers 120 are used to dissipate the heat, which is generated from electronic components (not shown in the figure) disposed on the substrate. The material of the thermal conductive insulating layer 120 can be diamond-like carbon. If necessary, the diamond-like carbon film can be doped with elements, such as F, Si, N, or B, to reduce the inner stress of the thermal conductive insulating layer 120. In the thermal conductive insulating layer 120, which is formed by the diamond-like carbon film doped with elements, such as F, Si, N, or B, the content of these elements (atom %) is unlimited, as long as these elements will not cause any deterioration to the semiconductor effect. The content of F or Si in the diamond-like carbon film may be 1-40 atom %. Preferably, the content of F or Si in the diamond-like carbon film is 5-20 atom %. The content of N or B in the diamond-like carbon film may be 1-30 atom %. Preferably, the content of N or B in the diamond-like carbon film is 5-15 atom %. In the present invention, the thermal conductive insulating layers 120 are disposed on the surfaces of the substrate 100, and made from diamond-like carbon with good thermal conductivity. Hence, when electronic components are operated, it is possible to dissipate heat to the environment effectively through the thermal conductive insulating layers 120.

With reference to FIG. 1, the circuit board of the present embodiment comprises a plurality of through-holes 130 vertically extended through the circuit board, wherein the through-holes 130 are filled with a conductive material 131. It should be noted that any kinds of materials with electrical conductivity can be used as the conductive material 131 in the present embodiment. For example, the material used in the conductive material 131 can be metal, but should not be limited to Cu. Ag, or a combination thereof. Because the through-holes 130 are filled with the conductive material 131, the patterned electrical conductive layer 135 disposed on the thermal conductive insulating layers 120 can be electrically connected through the through-holes 130. Hence, the circuit board of the present invention can be electrically connected to other components. Besides, an insulating layer 132 is formed on the sides of the through-holes 130, in order to electrically isolate the substrate 100 with the through-holes 130. The material of the insulating layer 132 is an insulating gel or a ceramic material. The material of the insulating layer 132 is, for example but not limited to, oxides, nitrides, carbides, epoxides, silica gel, or polyimide (PI).

In addition, the circuit board of the present invention is used to support an electronic component 150. As shown in FIG. 1, a solder layer 140 is formed on the patterned electrical conductive layer 135 of the circuit board, and the electronic component 150 is disposed on the circuit board through the solder layer 140. Herein, the electronic component 150 comprises a chip or a semiconductor device, such as a light emitting diode device (LED).

In the present invention, the thermal conductive insulating layers are formed on the upper surface and the lower surface of the substrate. Hence, not only the substrate but also the thermal conductive insulating layers of the present invention can dissipate the heat generated by electronic components, as compared with the conventional circuit board. Besides, the circuit board of the present invention includes the through-holes, so that the patterned electrical conductive layer disposed on the circuit board can be electrically connected. Hence, the circuit board of the present invention can be electrically connected to other components.

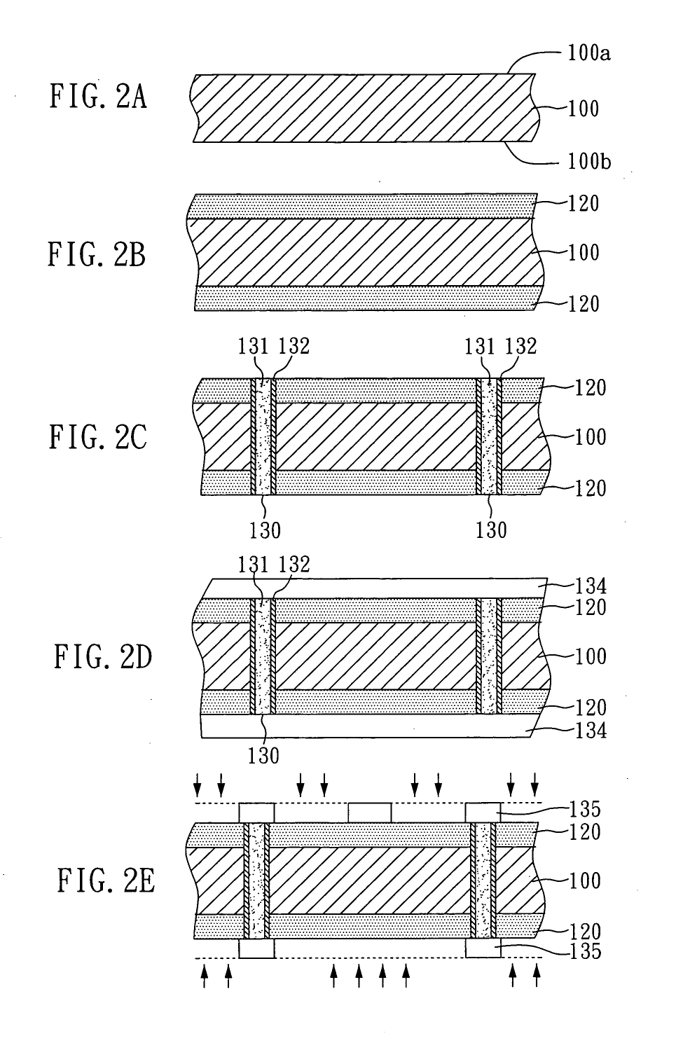

FIGS. 2A to 2E are flow charts for illustrating a process for manufacturing a circuit board of the present invention. First, with reference to FIG. 2A, a substrate 100 is provided, which has an upper surface 100a and a lower surface 100b. Then, as shown in FIG. 2B, thermal conductive insulating layers 120 are formed on the upper surface 100a and the lower surface 100b of the substrate 100. The thermal conductive insulating layers 120 are formed by chemical vapor deposition (CVD), and the condition of the chemical vapor deposition can be modified by a person skilled in the art without changes of the main principle of the present invention. Hence, the examples of the vapor deposition include filament chemical vapor deposition (filament CVD), plasma enhanced chemical vapor deposition (PECVD), or microwave plasma chemical vapor deposition (MPCVD), and other like methods. Preferably, in the present embodiment, the thermal conductive insulating layers are formed on the upper surface 100a and the lower surface 100b of the substrate at 200° C. or lower by PECVD. Besides, the thickness of the thermal conductive insulating layers 120 is unlimited. Preferably, the thermal conductive insulating layers 120 have a thickness of 0.1-30 μm. In the present embodiment, the thermal conductive insulating layers 120 have a thickness of 2-5 μm.

With reference to FIG. 2C, a plurality of through-holes 130 is formed, and vertically extends through the substrate 100 and the thermal conductive insulating layers 120. The through-holes 130 are formed by etching or machine drilling, for example. Besides, the through-holes 130 are filled with a conductive material 131. Additionally, an insulating layer 132 is formed on the sides of the through-holes 130. Then, as shown in FIG. 2D, an electrode layer 134 is formed on the surfaces of the thermal conductive insulating layers 120. The electrode layer 134 is formed by sputtering, electroplating, or electroless plating, wherein the material of the electrode layer 134 is Cr, Cu, or Ag. The thickness of the electrode layer 134 is unlimited, and depends upon the density of current applied from the electronic components (not shown in the figures). Preferably, the electrode layer has a thickness of 0.1-100 μm. In the present embodiment, the electrode layer 134 has a thickness of 20-40 μm.

Finally, with reference to FIG. 2E, parts of the electrode layer 134 are removed to form a patterned electrical conductive layer 135. The electrode layer 134 is removed by etching. After the patterned electrical conductive layer 135 is formed, the patterned electrical conductive layer 135 can be plated with Ni, Au, Ag , Sn or Sn alloy, and a combination thereof (not shown in the figures) if needed, in order to enhance the adhesive strength between the patterned electrical conductive layer 135 and electronic components.

### Embodiment 2

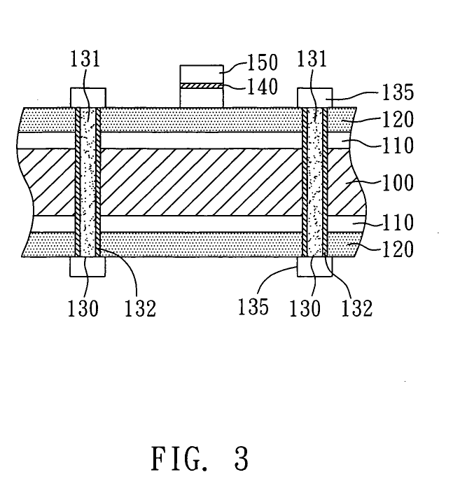

With reference to FIG. 3, there is shown a cross-sectional view of a circuit board according to another embodiment of the present invention. The circuit board and the method for manufacturing the same of the present embodiment are similar to those of the aforementioned embodiment. In comparison to the circuit board illustrated in the aforementioned embodiment, the circuit board of the present embodiment further comprises a plurality of ceramic layers 110 respectively formed on the upper surface and the lower surface of the substrate 100, and thermal conductive insulating layers 120 are formed on the surface of the ceramic layers 110. The material of the ceramic layers 110 is unlimited. Preferably, the material of the ceramic layers 110 is oxide, nitride, or boride. It should be noted that the method used for forming the ceramic layers 110 depends upon the material of the substrate 100. In the present embodiment, when the substrate 100 is a metal substrate, the ceramic layers 110 are formed by anodizing. When the substrate 100 is a semiconductor substrate, the ceramic layers 110 are formed by thermal treatment. Additionally, in the present embodiment, the ceramic layers 110 are located between the substrate 100 and the thermal conductive insulating layers 120, so it is possible to enhance the adhesive strength between the thermal conductive insulating layers 120 and the substrate 100. On the other hand, the ceramic layers 110 are good thermal conductors, so it is possible to improve the efficiency of the heat 5 dissipation of the circuit board of the present invention.

In conclusion, the circuit board of the present invention has thermal conductive insulating layers, which can improve the efficiency of the heat dissipation of the circuit board of the present invention. Hence, the heat, which is generated by electronic components disposed on the circuit board 10 or electronic circuits, can be effectively dissipated through the thermal conductive substrate and the thermal conductive insulating layers.

Therefore, the efficiency of the heat dissipation can be improved, and the stability and the lifetime of electronic components can be improved greatly.

In addition, the circuit board of the present invention has the through-holes. 15 Hence, the patterned electrical conductive layer disposed on the circuit board can be electrically connected by the through-holes. Therefore, the circuit board of the present invention can be electrically connected to other components.

Although the present invention has been explained in relation to its 20 preferred embodiment, it is to be understood that many other possible modifications and variations can be made without departing from the scope of the invention as hereinafter claimed.

What is claimed is:

1. A circuit board with high thermal conductivity, comprising:
a substrate having an upper surface, and a lower surface;
a plurality of thermal conductive insulating layers, respectively formed on the upper surface and the lower surface of the substrate;
a patterned electrical conductive layer, disposed on the surfaces of the thermal conductive insulating layers;
a plurality of through-holes, extended through the substrate, and electrically connected to the patterned electrical conductive layer; and
a solder layer, partially formed on the patterned electrical conductive layer.

2. The circuit board as claimed in claim 1, wherein the through-holes are filled with a conductive material, which comprises Cu, Ag, or a combination thereof.

3. The circuit board as claimed in claim 1, further comprising a plurality of ceramic layers formed on the upper surface and the lower surface of the substrate, and located between the substrate and the thermal conductive insulating layers.

4. The circuit board as claimed in claim 3, wherein the material of the ceramic layers comprises oxides, nitrides, or borides.

5. The circuit board as claimed in claim 1, wherein the substrate comprises a metal substrate, a semiconductor substrate, or a substrate made from other applicable material.

6. The circuit board as claimed in claim 5, wherein the material of the metal substrate comprises Al, Cu, or a combination thereof, and the material of the semiconductor substrate comprises Si, Ge, GeAs, or a combination thereof.

7. The circuit board as claimed in claim 1, wherein the material of the thermal conductive insulating layers comprises diamond-like carbon.

8. The circuit board as claimed in claim 7, wherein the thermal conductive insulating layers have a dopant, which comprises F, Si, N, B, or a combination thereof.

9. The circuit board as claimed in claim 8, wherein the content of F or Si in the diamond-like carbon film is 1-40 atom % or 5-20 atom %.

10. The circuit board as claimed in claim 8, wherein the content of N or B in the diamond-like carbon film is 1-30 atom % or 5-15 atom %.

11. The circuit board as claimed in claim 1, wherein the thermal conductive insulating layers have a thickness of 0.1-30 μm, or 2-5 μm.

12. The circuit board as claimed in claim 1, further comprising an insulating layer formed on the sides of the through-holes.

13. The circuit board as claimed in claim 12, wherein the material of the insulating layer comprises insulating gel, a ceramic material, oxides, nitrides, carbides, epoxides, silica gel, or polyimide.

14. The circuit board as claimed in claim 1, wherein the material of the patterned electrical conductive layer comprises Cr, Cu, Ni, Au, Ag, or a combination thereof.

15. The circuit board as claimed in claim 1, wherein the circuit board is used to support an electronic component, which is disposed on the patterned electrical conductive layer of the circuit board through the solder layer, and the electronic component is a chip, or a semiconductor device.

16. The circuit board as claimed in claim 15, further comprising a metal layer disposed on the patterned electrical conductive layer to enhance the adhesive strength with the electronic component.

17. The circuit board as claimed in claim 16, wherein the metal layer comprises Ni, Au, Ag, Sn or Sn alloy, and a combination thereof.

18. A method for manufacturing a circuit board, comprising following steps:
providing a substrate having an upper surface, and a lower surface;
forming a plurality of thermal conductive insulating layers, which are respectively formed on the upper surface, and the lower surface of the substrate;
forming a plurality of through-holes, which are extended through the substrate, and the thermal conductive insulating layers;
forming an electrode layer on the surfaces of the thermal conductive insulating layers;
removing parts of the electrode layer to form a patterned electrical conductive layer; and
forming a solder layer, which is partially formed on the patterned electrical conductive layer.

19. The method as claimed in claim 18, wherein the through-holes are formed by etching, or machine drilling.

20. The method as claimed in claim 18, wherein the thermal conductive insulating layers are formed by vapor deposition.

21. The method as claimed in claim 18, further comprising: adding a dopant into the thermal conductive insulating layers, wherein the material of the thermal conductive insulating layers comprises diamond-like carbon, and the dopant comprises F, Si, N, B, or a combination thereof.

22. The method as claimed in claim 18, further comprising: filling the through-holes with a conductive material, wherein the conductive material comprises Cu, Ag, or a combination thereof.

23. The method as claimed in claim 18, further comprising: forming an insulating layer on the sides of the through-holes, wherein the material of the insulating layer comprises insulating gel, or a ceramic material.

24. The method as claimed in claim 18, wherein the electrode layer is formed by sputtering, electroplating, or electroless plating.

25. The method as claimed in claim 18, wherein the electrode layer is removed by etching.

26. The method as claimed in claim 18, further comprising: forming a metal layer on the patterned electrical conductive layer after forming the patterned electrical conductive layer, wherein the metal layer comprises Ni, Au, Ag, Sn or Sn alloy, and a combination thereof.

27. The method as claimed in claim 18, further comprising: forming a plurality of ceramic layers on the upper surface and the lower surface of the substrate.

28. The method as claimed in claim 27, wherein the ceramic layers are formed by anodizing, or thermal treatment.
